(19) United States
(12) Patent Application Publication
(10) Pub. No.: US 2024/0273266 A1
(43) Pub. Date: Aug. 15, 2024

(54) INFORMATION PROCESSING DEVICE, INFORMATION PROCESSING METHOD, AND NON-TRANSITORY COMPUTER READABLE MEDIUM

(71) Applicant: ENEOS Corporation, Tokyo (JP)

(72) Inventor: Tasuku ONODERA, Tokyo (JP)

(73) Assignee: ENEOS Corporation, Tokyo (JP)

(21) Appl. No.: 18/635,288

(22) Filed: Apr. 15, 2024

Related U.S. Application Data
(63) Continuation of application No. PCT/JP2022/034935, filed on Sep. 20, 2022.

(30) Foreign Application Priority Data
Oct. 15, 2021 (JP) 2021-169866

(51) Int. Cl. G06F 30/27

(52) U.S. Cl. CPC G06F 30/27

(57) ABSTRACT

An information processing device includes a memory storing information on a force field model, and a processor. The processor defines a molecular model representing a population of molecules having a thickness in a third direction and the third direction intersecting the first direction and the second direction, and extending in a first direction and a second direction; and a first solid wall model and a second solid wall model that represent solid walls, executes molecular dynamics simulation in which a force is applied to the second solid wall model in a first model in which the first solid wall model is fixed and the molecular model is interposed between the first solid wall model and the second solid wall model, by using the force field model, and calculates a stress of the molecular model acquired as a result of the molecular dynamics simulation.

### CROSS REFERENCE TO THE RELATED APPLICATIONS

This application is continuation application of International Application No. PCT/JP2022/034935, filed on Sep. 20, 2022, which claims priority to Japanese Application No. 2021-169866, filed on Oct. 15, the entire contents of which are incorporated herein by reference.

### FIELD

The present disclosure relates to an information processing device, an information processing method, a program, and a non-transitory computer readable medium.

### BACKGROUND

Complex phenomena such as structural changes of molecules and chemical reactions occur on surfaces and interfaces where various fluids such as aqueous solutions, oils, and greases are in contact with or in sliding contact with solids. In order to estimate physical properties such as wettability, adsorbability, viscosity, a friction coefficient, a traction coefficient, and a wear coefficient based on the expressed phenomenon, it is one of general methods to use physical simulation such as a molecular dynamics method.

In the physical property estimation by molecular simulation, accuracy of a force field in which a relationship between an interatomic distance and energy is tabulated in addition to a calculation algorithm affects accuracy of an estimated value. The force field based on the classical theory has an advantage of high calculation efficiency but has a problem of low accuracy and being incapable of coping with an inexperienced system. Meanwhile, when the force field is constructed based on the quantum theory, a highly accurate force field can be obtained, but the force field is tuned to a specific system. Therefore, versatility (generality or universality) is low, and enormous calculation time is required to acquire the force field required for physical property estimation.

For example, a method for estimating a traction coefficient by a force field based on classical theory is provided, but the traction coefficient is estimated for a specific fluid, and good agreement with an experimental value is shown. However, in the force field based on the classical theory, the accuracy of estimation cannot be maintained for a novel compound, a mixed system in which two or more compounds are mixed at an arbitrary rate, an ionic liquid having polarization, and the like, and there is a problem in accuracy and versatility. It is desired, from academic and industrial fields, to establish a fluid physical property estimation method with a force field having calculation efficiency, accuracy, and versatility.

### BRIEF DESCRIPTION OF DRAWINGS

FIG. 1 is a block diagram schematically illustrating an information processing device according to an embodiment.

FIG. 2 is a diagram illustrating an example of model formation according to the embodiment.

FIG. 3 is a flowchart illustrating processing of the information processing device according to the embodiment.

FIG. 4 is a cross-sectional view schematically illustrating a model according to the embodiment.

FIG. 5 is a cross-sectional view schematically illustrating a model according to the embodiment.

FIG. 6 is a diagram illustrating an output example of a shear stress according to the embodiment.

FIG. 7 is a diagram illustrating an output example of a friction coefficient according to the embodiment.

FIG. 8 is a diagram illustrating a simulation result of a friction coefficient according to the embodiment.

FIG. 9 is a diagram illustrating an example of a model of a solid wall according to the embodiment.

FIG. 10 is a graph illustrating an example of an output of a friction coefficient according to the embodiment.

FIG. 11 is a diagram illustrating an example of a model of a solid wall according to the embodiment.

FIG. 12 is a graph illustrating an example of an output of a friction coefficient according to the embodiment.

FIG. 13 is a diagram illustrating an example of an input according to the embodiment.

### DETAILED DESCRIPTION

According to one embodiment, an information processing device includes a memory that stores information on a force field model trained by machine learning, and a processor. The processor defines a molecular model that represents a population of molecules having a thickness in a third direction with respect to a first direction, a second direction intersecting the first direction, and the third direction intersecting the first direction and the second direction, and extending in the first direction and the second direction; and a first solid wall model and a second solid wall model that represent solid walls, executes molecular dynamics simulation in which a force is applied to the second solid wall model in a first model in which the first solid wall model is fixed and the molecular model is interposed between the first solid wall model and the second solid wall model, by using the force field model, and calculates a stress of the molecular model acquired as a result of the molecular dynamics simulation.

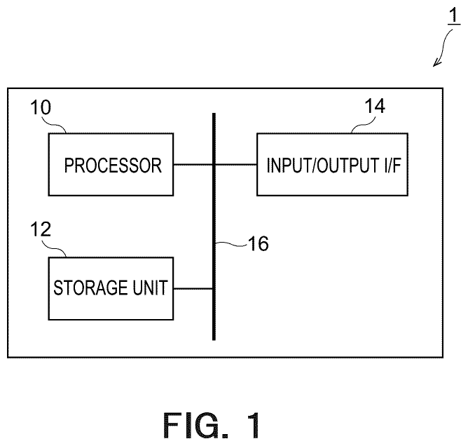

FIG. 1 is a block diagram schematically illustrating an information processing device according to an embodiment. The information processing device 1 includes a processor 10, a storage unit 12, and an input/output interface (hereinafter, referred to as an input/output I/F 14) and is appropriately connected to each other via a bus 16. The information processing device 1 acquires a predetermined physical property by inputting a type, a position, and the like of an element for an atom. Note that the information processing device 1 includes components required for appropriately executing information processing in addition to those illustrated in the drawing.

The processor 10 executes calculation processing on the information processing device 1. The processor 10 includes, for example, a processing circuit such as a central processing unit (CPU) or a graphics processing unit (GPU). Furthermore, the processor 10 may control start and other operations of the information processing device 1. When an accelerator is used, an external processor connected from the processor 10 via the input/output I/F 14 may be used as an accelerator. That is, the processor 10 for performing calculation may be provided outside the information processing device 1.

The storage unit 12 stores data and the like required for starting the information processing device 1 and estimating physical properties in the information processing device 1. The storage unit 12 includes a storage medium such as an appropriate memory and storage. Such a storage medium includes a transitory or non-transitory computer readable medium, and the processor 10 accesses the storage medium to execute required operations. When the information processing of the information processing device 1 by software is specifically realized by using hardware resources, the storage unit 12 may store a program, an execution file, and the like for executing the information processing of the software. Furthermore, the storage unit 12 may store information such as data in the process of information processing and physical properties acquired as a result of the information processing.

The input/output I/F 14 is an interface that connects the processor 10 and the storage unit 12 to the outside. The information processing device 1 receives a request from a user via the input/output I/F 14 and outputs appropriate data or the like to an appropriate portion. The input/output I/F 14 can also be used as an interface for connecting the processor 10 and the storage unit 12 to an external device when the processor 10 executes calculation by using the external device. This connection may be, for example, a wired or wireless network line or may be other connection means such as a serial cable or a parallel cable.

The information processing device 1 estimates a physical property value desired to be acquired by the user by executing the molecular dynamics simulation. Examples of the molecular dynamics simulation includes a classical method, a method based on the quantum theory, and a method (NNP) using a neural network model trained by machine learning. In the present disclosure, the information processing device 1 acquires physical property values by executing a molecular dynamics simulation based on NNP.

The physical property value is, for example, a friction coefficient of an interface at which a solid and a liquid are in contact. The information processing device 1 acquires a mechanical response at an interface between substances (solid and liquid) with high accuracy in a short period of time by using NNP and acquires a friction coefficient by a temporal change of the mechanical response. Note that the force field model based on NNP may be a model trained by using simulation results based on quantum mechanics as teacher data.

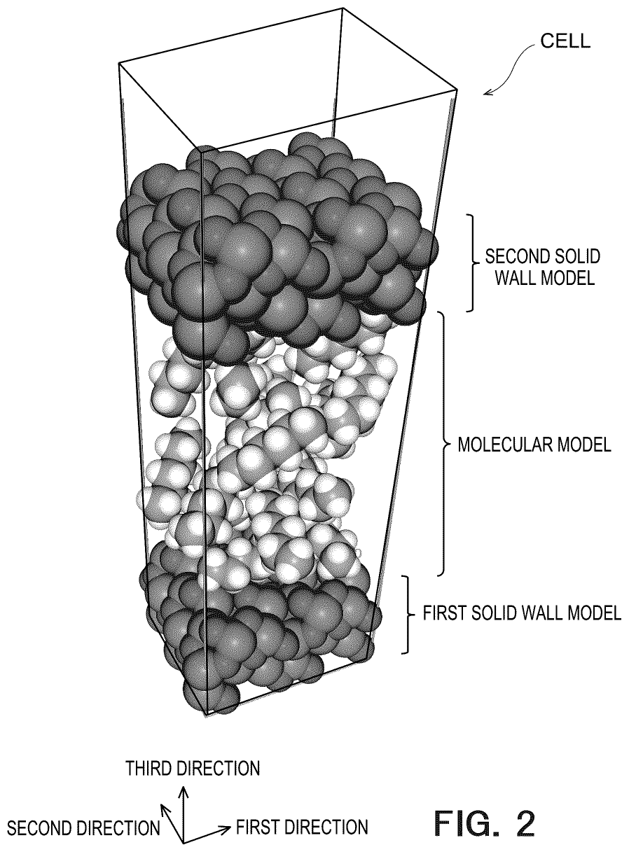

FIG. 2 illustrates a non-limiting example of a model to be subjected to the molecular dynamics simulation according to the present embodiment. The processor 10 inputs a set of atoms illustrated in FIG. 2 as a cell into a force field model based on the NNP. Note that the composition of the configuring molecules is illustrated as a non-limiting example and is not limited thereto.

The model to be input to the force field model is a model formed in the cell. In the present embodiment, a model indicating a molecular structure of a target with which physical properties with respect to the solid wall are desired to be obtained is formed between the solid walls having a thickness in the third direction and extending in the first direction and the second direction.

The solid wall is formed by two models of a first solid wall model of which the position is fixed and a second solid wall model of which the position is fixed or movable. A model representing an input cell is formed by arranging a molecular model for forming a molecular structure of the target between these two solid walls.

That is, the first model in which the molecular model is interposed between the two solid wall models is used as the cell model. Among the first models, in particular, a model in which the second solid wall model is fixed is set as the second model, and the processor 10 moves the second solid wall model to the first model with the second model as an initial value, so that it is possible to acquire various characteristic values, in a case where the second solid wall applies a force to the molecular model, or the second solid wall moves to the first solid wall.

The molecular model is, for example, a model representing a substance indicating a population of molecules, a liquid, a crystal, or an amorphous solid. The molecular model is not limited to these examples, and a substance that exists between the solid walls and with which physical properties having an interface with the solid walls are desired to be acquired may be modeled as a molecular model.

A model in the cell is formed by defining each of these models. In the present embodiment, the cell to be input to the force field model is a model having a periodic boundary condition. By inputting the cell model to the force field model, the interatomic potential is calculated, and various physical properties are estimated.

The size of the cell may be any size in which the simulation is appropriately executed, but may be, for example, such a size in which the configuration of the molecule in the molecular model includes patterns of sufficiently various positions and postures. The first solid wall model or the second solid wall model may be disposed at a position sufficiently separated from the lower surface or the upper surface of the cell in the third direction. With this arrangement, the influence of the interatomic potential between the first solid wall model and the second solid wall model can be ignored.

Hereinafter, a case where the molecular model interposed between the solid walls is a liquid is described.

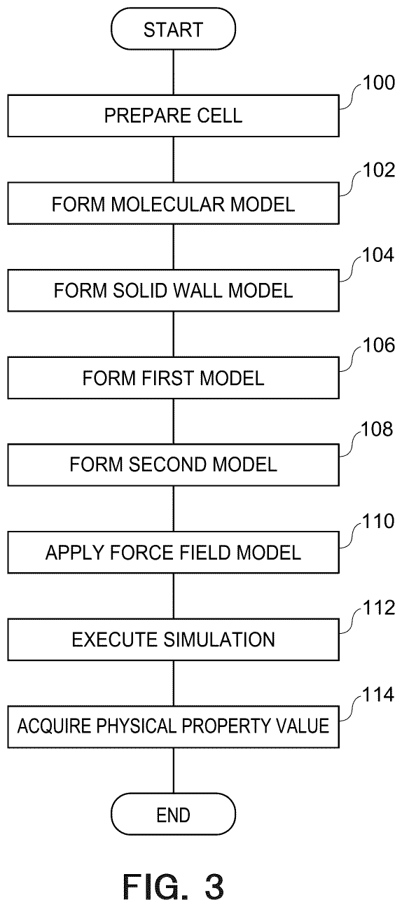

FIG. 3 is a flowchart illustrating processing of the information processing device 1 according to the embodiment. A non-limiting example of the processing is described with reference to FIG. 3.

First, the processor 10 prepares a cell to be used for molecular dynamics simulation (S100). A model used for molecular dynamics simulation is generated by appropriately arranging atoms in the space of the prepared cell.

Next, the processor 10 forms a molecular model in the cell (S102). As described above, this molecular model is a model including liquid molecules interposed between the solid walls. Note that the molecular model is not limited to a model of a substance configured with one type of molecule and may be a model of a liquid in which a plurality of types of molecules are mixed.

Next, the processor 10 forms a model of the solid wall in the cell (S104). As illustrated in FIG. 2, the solid walls are a first solid wall model and a second solid wall model formed on the lower side and the upper side of the molecular model. For example, in a case where the liquid is lubrication oil, the distance between these solid walls may be defined assuming, for example, a distance between objects to be smoothly operated by the lubrication oil.

S102 and S104 may not be executed in this order but may be executed in the reverse order or in parallel.

Next, the processor 10 generates a first model in which the first solid wall model is fixed and, the second solid wall model can move on a plane formed by the first direction and the second direction (S106).

Next, the processor 10 generates a second model having an interface in contact with each solid wall model in a state where the first solid wall model and the second solid wall model are fixed, and the molecular model is interposed between these models (S108). This second model can also be formed as a special case of the first model.

S106 and S108 may not be executed in this order but may be executed in the reverse order or in parallel. When the steps are executed in the reverse order, the processor 10 may form the first model as a special case of the second model based on the second model.

Next, the processor 10 forms a force field model (S110). This force field model is a model based on NNP and is a model trained in advance by machine learning. For example, the processor 10 reads various parameters and hyperparameters stored in the storage unit 12 to form a neural network model and uses the neural network model as a force field model.

Next, the processor 10 executes the molecular dynamics simulation by inputting the generated first model and the generated second model to the force field model (S112). For example, by using the second model as an initial value, the processor 10 executes simulation while controlling the second solid wall model so as to apply pressure, shear force, and the like to the molecular model by using the first model.

Next, the processor 10 acquires a desired physical property value from the simulation result (S114). The processor 10 may further execute simulation by using the acquired physical property values or may output appropriately acquired physical property values.

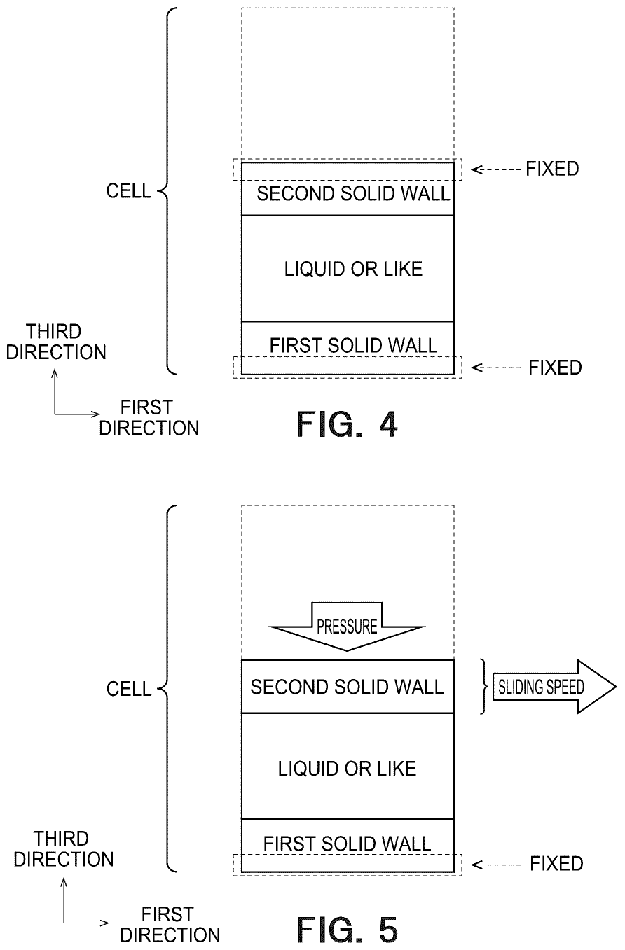

FIG. 4 is a cross-sectional view schematically illustrating a second model used for the molecular dynamics simulation. FIG. 4 is a cross-sectional view of the model illustrated in FIG. 2 as viewed from the second direction.

The area in the broken line and to the lower surface of the first solid wall is an area of the cell, each model defined in the cell is input to the force field model, and the molecular dynamics simulation is executed. A model representing the first solid wall, the second solid wall, the liquid, and the like is generated in the cell. The liquid or the like is disposed so as to be interposed between the first solid wall and the second solid wall.

When fixing the first solid wall and the second solid wall, the processor 10 can realize the fixed state by keeping the coordinates of the atoms fixed during the execution of the simulation at the coordinates of the same position as the first model.

In the second model, the lower surface of the first solid wall is fixed to generate the first solid wall model, and the upper surface of the second solid wall is fixed to generate the second solid wall model. The processor 10 executes the molecular dynamics simulation, for example, with this state as an initial state.

The processor 10 executes the processing of S108 as described above.

FIG. 5 is a cross-sectional view schematically illustrating a first model used for the molecular dynamics simulation. FIG. 5 is a cross-sectional view from the same viewpoint as FIG. 4.

As illustrated in FIG. 4, the area in the broken line and to the lower surface of the first solid wall is an area of the cell, each model defined in the cell is input to the force field model, and the molecular dynamics simulation is executed. A model representing the first solid wall, the second solid wall, the liquid, and the like is generated in the cell. The liquid or the like is disposed so as to be interposed between the first solid wall and the second solid wall.

In the first model, the first solid wall is fixed as in the case of the second model. On the other hand, the second solid wall is not fixed. Therefore, the first model can arbitrarily apply a pressure in a direction parallel to the third direction and a shear force in a direction parallel to the first direction (a direction parallel to a plane formed by the first direction and the second direction, for simplicity, hereinafter referred to as a first direction) to the second solid wall. Further, since the second solid wall is not fixed, it is also possible to form a model in which the second solid wall moves in each step of the simulation.

That is, the processor 10 (or the user) can set a direction obtained by combining the first direction and the second direction as the direction in which the shear force is applied. The direction obtained by combining the first direction and the second direction is a direction obtained by adding a vector indicating the first direction and a vector indicating the second direction by arbitrary weighting. Hereinafter, the portion parallel to the first direction may be appropriately read as the combined direction.

In addition, it is not required that the third direction component is 0 in a strict sense, and the processor 10 can also execute simulation as a direction in which a certain vector has a minute component in the third direction and acquire a result in a case where the vector has a component in the third direction.

When applying a pressure parallel to the third direction to the second solid wall, the processor 10 can define the pressure as follows, for example. The processor 10 acquires information on the number N of atoms to which pressure is to be applied, an area A where the second solid wall and the liquid layer are in contact with each other, and the pressure P desired to be applied. In this case, the applied force F can be represented by F=P×A. Then, the processor 10 can realize a predetermined pressure in the force field by applying an equivalent force F/N (=P×A/N) to the atom to which the pressure is desired to be applied for each step of simulation.

When applying a sliding speed parallel to the first direction to the second solid wall, the processor 10 can define the sliding speed as follows, for example.

The processor 10 acquires a sliding speed v desired to be applied, multiplies v by integration time Δt for each step used in the simulation, and calculates a displacement Δr=v×Δt per step. Then, the processor 10 can realize a predetermined sliding speed by setting coordinates r of the slip direction (for example, in the first direction) of all the atoms to which the sliding speed is desired to be applied for each step of simulation as r+Δr.

The processor 10 executes the processing of S106 as described above. For example, when the number of steps is n, the first model is generated from the next step in the initial state, the pressure and displacement are applied to the second solid wall to form the second solid wall model in the next step, and the first model including the second solid wall model is generated. The processor 10 generates the first model up to n steps and ends the processing of S106.

Note that the processor 10 may generate the second model in which the second solid wall model is fixed to the first model (as a special state of the first model) as the initial state in which the pressure and the shear force are not applied (S108). As described above, the processor 10 may first generate the second model (S108) and generate the first model in which the pressure and the shear force are applied to the second solid wall model based on the second model (S106).

As described above, the fixed state of the atom or the displacement state due to the velocity can be defined based on the position of the atom in the model defined for each time (step).

Next, the processor 10 executes the molecular dynamics simulation by inputting the generated first model and the generated second model to the force field model.

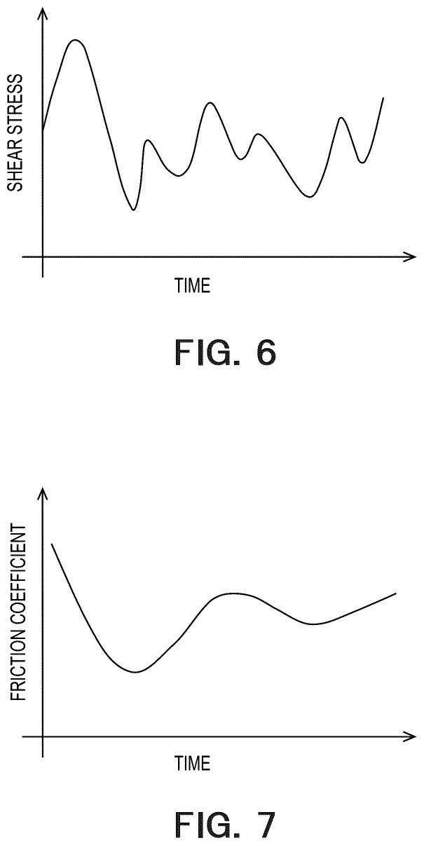

FIGS. 6 and 7 are diagrams schematically illustrating an example of a shear stress and a friction coefficient acquired by molecular dynamics simulation in the present embodiment. For example, it is assumed that the shear stress with respect to time as illustrated in FIG. 6 is acquired by the above simulation.

The processor 10 can acquire the temporal change of the friction coefficient as illustrated in FIG. 7 by dividing the shear stress by the pressure applied to the second solid wall in the first model.

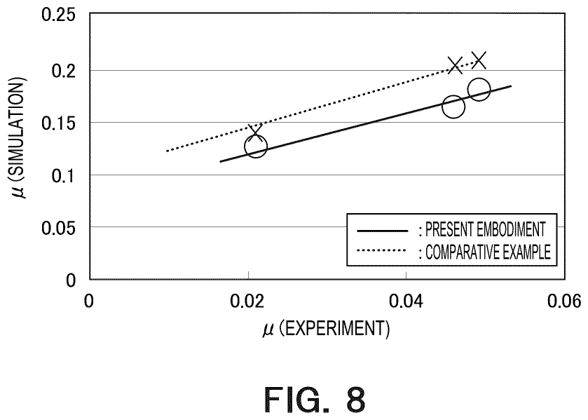

FIG. 8 is a graph for comparing the friction coefficient acquired in the present embodiment with an experimental value. In addition, values calculated by classical molecular dynamics simulation are illustrated as comparative examples. The result according to the present embodiment is indicated by circles and a solid line, and the result of the comparative example is indicated by crosses and a dotted line. The relationship between the friction coefficient estimated by the simulation and the friction coefficient acquired by the experiment is plotted with the circles and the crosses. The solid line and the broken line are straight lines obtained by approximating the circles and the crosses.

As illustrated in FIG. 8, as the friction coefficient estimated in the present embodiment, a friction coefficient closer to the experimental value than the comparative example is acquired, and it can be understood that good results can be acquired.

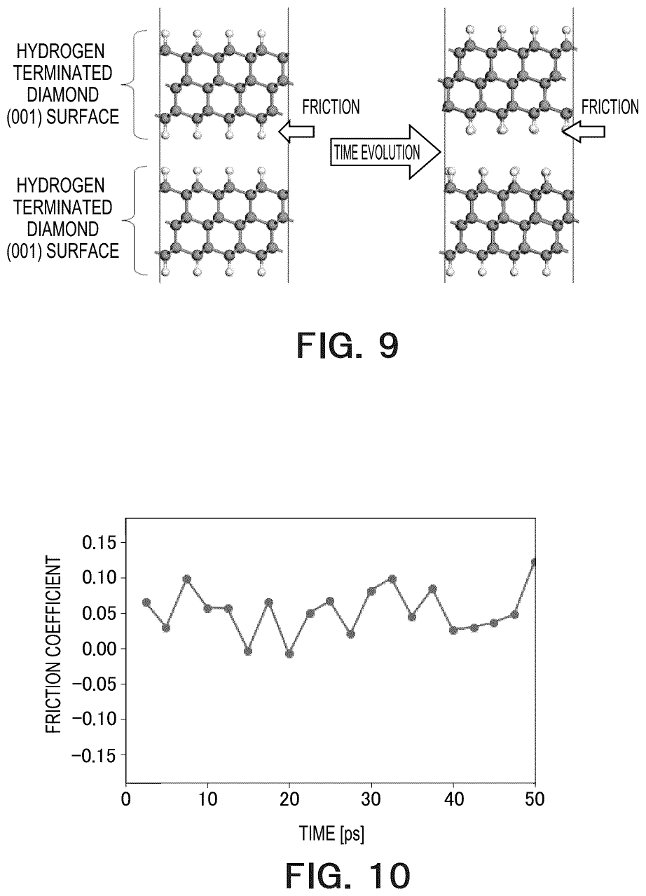

FIGS. 9 and 10 are diagrams illustrating an example of a case where no chemical reaction occurs between the liquid and the solid wall in the present embodiment. For example, as illustrated in FIG. 9, it is assumed that the solid wall is formed of diamond and has a structure in which a hydrogen atom (hereinafter, it is described as H) exists at the terminal on the liquid side. In such a case, no chemical bond occurs at the interface with the liquid.

For example, a pressure and a shear force is applied so that the state illustrated in the left drawing transitions to the state illustrated in the right drawing, but a chemical reaction does not particularly occur in the simulation.

As a result, the low friction state is maintained as illustrated in FIG. 10.

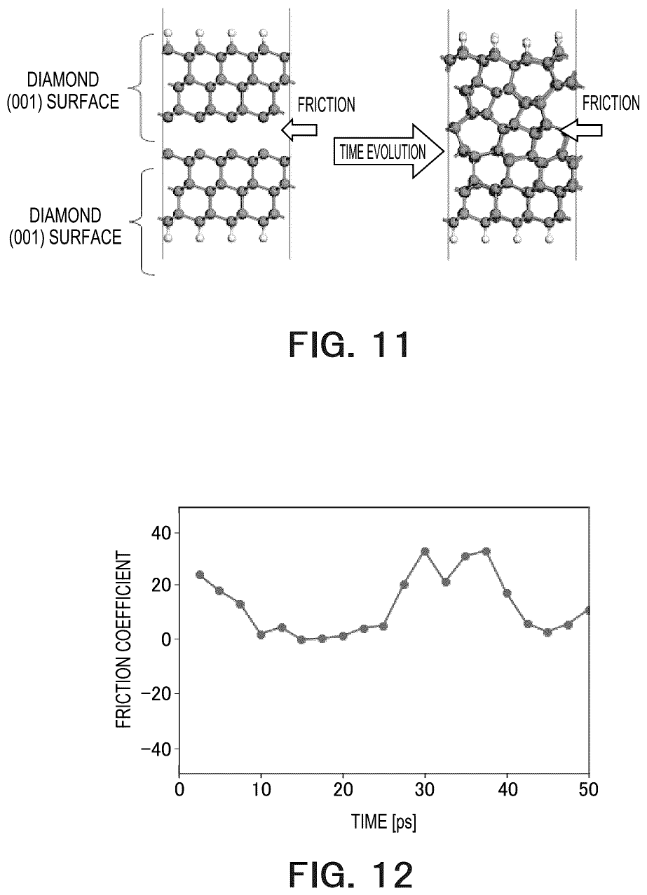

FIGS. 11 and 12 are diagrams illustrating an example of a case where a chemical reaction occurs between a liquid and a solid wall in the present embodiment. For example, when a liquid exists as a lubrication oil, a chemical reaction between the solid walls via the liquid may occur due to the pressure. In FIG. 11, the solid wall is a diamond structure without H at the terminal. In such a case, unlike FIG. 9, by applying pressure and a shear force from the state of the left drawing, the solid walls cause a chemical reaction and are bond to each other as illustrated in the right drawing.

As a result, the friction coefficient greatly increases or decreases as illustrated in FIG. 12 according to the number of chemical bonds, the crystal structure, and the like.

In general, in the classical molecular dynamics simulations, it is difficult to supplement such a state, and the friction coefficient cannot be appropriately acquired. In addition, although it is possible to infer such a state in the quantum molecular dynamics simulation, an enormous calculation time and calculation resources are required, and thus it is difficult to acquire the result in real time.

As described above, according to the present embodiment, since the simulation only inputs the positions of the atoms and the like, the applied pressure, and the like to the trained model and acquires the result, the result can be acquired in time of about several minutes to several hours, and the speed can be significantly increased as compared with the quantum simulation. Furthermore, as compared with these methods, as illustrated in FIG. 8, since a value closer to the experimental value is estimated as compared with the comparative example, the result with high accuracy can be acquired, and thus inference corresponding to an unknown substance or an unknown combination of substances can be realized. That is, versatility and robustness can be improved. In addition, it is possible to automatically determine whether there exists a chemical reaction at the interface and to acquire an appropriate physical property value only by inputting the molecular structure and the like.

For example, when the molecular model is a liquid (fluid), what kind of substance is optimal as a lubrication oil between the solids in contact with each other can be inferred by changing the model of the liquid to various molecules without changing the model of the solid wall. In addition, the material of the solid wall may be variously changed according to the purpose, and inference may be made so as to have an appropriate friction coefficient or the like.

Note that the processor 10 can also acquire a relationship between an interatomic distance and energy for two or more types of elements and a combination thereof by inputting the first model and the second model to the force field model and form a database of the relationship in advance. By forming the database in this manner, calculation with a higher speed can be realized by using the information registered in the database.

In addition to the above, various physical properties can be acquired by using the present embodiment. For example, the processor 10 may calculate adsorption energy or interaction energy based on energy acquired in molecular dynamics simulation by using a force field model formed by NNP. The processor 10 can calculate adsorption energy between the molecules configuring the liquid interposed between the solid walls and the solid walls, or interaction energy between the solid walls or between the molecules of the liquid.

The processor 10 may further acquire information such as a temporal change (temporal development) in the position and velocity of the molecule configuring the liquid based on the information on the energy (and force) acquired via the NNP. Then, the processor 10 can also acquire physical property values represented by the atomic distribution, the diffusion coefficient, the orientation degree, the viscosity, and the like of the molecular model based on the acquired temporal change of the position and velocity of the molecules configuring the liquid.

For example, the processor 10 can acquire the adsorption energy by acquiring energy in a state in which molecules are adsorbed to each other and energy in a state in which molecules are not adsorbed to each other, via the NNP, and calculating a difference between these energies. Since the system is stabilized by adsorption between molecules, the adsorption energy indicates how stable the system is.

For example, the processor 10 can estimate the atomic distribution by dividing the coordinates in the third direction at predetermined intervals and generating a mesh. More specifically, the processor 10 can acquire the atomic distribution by acquiring the number of atoms existing in each generated mesh. That is, the atomic distribution is acquired based on the position information of the atom.

The processor 10 can also acquire the atomic distribution for each time. By using this atomic distribution, for example, in a case where lubrication oil molecules contain oxygen atoms like alcohols and carboxylic acids, it is possible to acquire information on a structure of forming a kind of coating closely in the vicinity of a solid wall or the like.

The processor 10 can acquire the diffusion coefficient, for example, from mean square displacement (MSD). The MSD represents how much atoms are displaced during a certain period of time. This MSD can be acquired from position information of atoms. By using this diffusion coefficient, for example, not only the molecular structure of the oil but also information such as how fluid the oil is depending on the pressure and the shear rate can be acquired.

For example, the processor 10 can acquire the orientation degree based on the position information of the atom. The orientation degree indicates, for example, information on the angle at which the lubrication oil molecules are in contact with (stick to) the solid wall. For example, it is possible to acquire information regarding the oil film structure that linear molecules such as normal alkanes are comparatively parallel oriented, while branched alkanes and the like are randomly oriented, and that alcohol, carboxylic acid, and the like having a polar group are uniformly aligned at a predetermined angle. The processor 10 can also obtain the distribution of molecules in the third direction based on this information.

For example, the processor 10 can acquire viscosity based on the velocity information of the molecule. More specifically, the processor 10 can acquire the viscosity by calculating the value of the autocorrelation function of the velocity in a certain direction (as an example, the first direction or the second direction) of the atoms configuring the molecule and executing mathematical processing.

As described above, in the present disclosure, various physical property values can be acquired for the molecule interposed between the solid walls by using NNP. However, the physical property values listed above are examples, and it is possible to acquire, for example, a physical property value or the like as a result of being affected by the interface between the molecule and the solid wall regarding the molecule and the solid wall in the same situation.

Although the molecular model is set as a liquid, the liquid may be a liquid formed of a pure material configured with one or more types of molecules or a material obtained by mixing a plurality of materials. The molecular model is not limited to a liquid. For example, the molecular model may be a crystal or amorphous solid. In these cases, physical properties such as a friction coefficient can be similarly acquired. Further, the molecular model may be a gas or a solid. In these cases, physical properties such as a friction coefficient can be acquired.

In the above embodiment, the simulation is executed assuming that the second solid wall model moves (applies a shear force), but the present disclosure is not limited thereto. For example, the positions of both the first solid wall model and the second solid wall model may be fixed, and the molecular model may be moved.

The solid wall is formed on a plane but is not limited thereto. As a further non-limiting example, it is also possible to appropriately infer the friction coefficient between non-planar solids such as bearings and fluids by setting circumferential, cylindrical and/or spherical solid walls.

Furthermore, it is inferred in what state the second solid wall model is with respect to the fixed first solid wall model via the molecular model. However, by fixing both the solid walls and applying a force to or moving the molecular model, it is possible to infer on what friction coefficient the liquid moves in the area interposed between the solid walls and what kind of reaction occur at the interface. Furthermore, a model having a cylindrical cavity may be used instead of a model of a solid wall, and for example, it is also possible to infer a state (for example, friction coefficient) of liquid, gas, or the like to which pressure passing through a straw-shaped object is applied.

Although the generation of the model and the like is described in the above-described embodiment, the advantageous point of using the force field model based on the NNP is not limited to the calculation time and accuracy. The advantage of this approach is that usability can also be improved. That is, the simulation can be realized without finely setting the information input by the user. This is because an appropriate simulation is realized based on the position of the atom in the NNP.

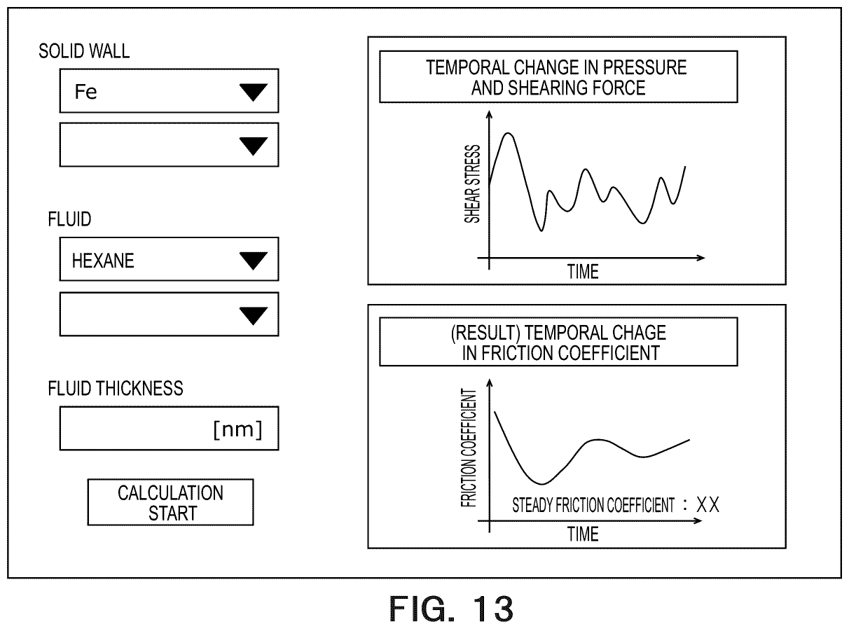

FIG. 13 is a diagram illustrating an example of information input by the user to realize the simulation according to the present embodiment as a graphical user interface (GUI). For example, the substance of the solid wall and the substance configuring the fluid may be set in a selectable form. The user can cause the processor 10 to execute the simulation by appropriately selecting the set substance. The thickness of the fluid can also be input.

The processor 10 may define the solid wall based on the input substance to be separated by the thickness of the input fluid and define the fluid based on the input substance therebetween as the molecular model.

Although the information that can be input is simple, the processor 10 can resultantly acquire the time change of the friction coefficient, by changing the pressure and the shear force in time with only the above information. The output result is not limited to the friction coefficient and may be the physical property values exemplified above. The processor 10 may infer and output an appropriate physical property value according to selection of the user.

For example, when the shear stress changes as illustrated in the upper right part of the display of FIG. 13, a change in the friction coefficient with time as illustrated in the lower right part can be acquired. Furthermore, the information processing device 1 can also acquire and output a steady friction coefficient. The steady friction coefficient can be acquired as an average value of friction coefficients in a time domain in which a change in friction coefficient is within a predetermined width.

The upper right part of the graph corresponds to FIG. 6 and may be automatically generated by an application or may be designated by the user. If designated by the user, this transition can be one that allows the user to directly input shear stress (and/or pressure in vertical direction). In addition, the transition may be generated automatically by the processor 10 based on a condition designated by the user.

Based on the temporal change, the processor 10 generates the first model for each time (step) and executes the simulation. Then, the information processing device 1 may output the final result to the lower right part.

Furthermore, although the GUI is illustrated, the present disclosure is not limited thereto, and for example, an interface for accessing a library such as an application programming interface (API) or a class may be used.

An interface that can input information for further limitation may be used.

As described above, according to the present embodiment, the input information can be simple information such as the substance configuring the solid wall, the substance configuring the fluid, and the thickness of the fluid. By using the force field by the NNP, it is possible to infer an appropriate physical property value for such a simple input.

The mode in the present disclosure can be applied, for example, in a situation where a solid and a molecular structure such as a liquid come into contact with each other among components configuring an engine of an automobile, a suspension, an industrial machine, an air conditioner, a refrigerator, and the like. The mode can also be applied to space-related technologies and vacuum technologies.

The foregoing embodiments can be summarized as follows.

<1> An information processing device comprising:

a memory (12) storing information on a force field model trained by machine learning; and

a processor (10) configured to:
define a molecular model that represents a molecular structure of a target having a thickness in a third direction with respect to a first direction, a second direction intersecting the first direction, and the third direction intersecting the first direction and the second direction, and extending in the first direction and the second direction; and a first solid wall model and a second solid wall model that represent solid walls;
execute molecular dynamics simulation in which a force is applied to the second solid wall model in a first model in which the first solid wall model is fixed and the molecular model is interposed between the first solid wall model and the second solid wall model, by using the force field model; and
calculate a stress of the molecular model acquired as a result of the molecular dynamics simulation.

<2> The information processing device according to <1>, in which the force field model is a model based on a neural network potential (NNP).

<3> The information processing device according to <2>, in which the molecular dynamics simulation is executed by using an interatomic potential calculated based on the NNP.

<4> The information processing device according to <3>, in which the molecular model is a model showing a population of molecules, a liquid, a crystal, or an amorphous solid.

<5> The information processing device according to <3> or <4>, in which the processor (10) executes a molecular dynamics simulation in a second model in which both the first solid wall model and the second solid wall model are fixed, and executes calculation in the first model with a result acquired in the second model as an initial state.

<6> The information processing device according to any one of <3> to <5>, in which the processor (10) executes a molecular dynamics simulation by applying a pressure along the third direction and a shear force in a direction obtained by combining the first direction and the second direction to the second solid wall model in the first model to acquire a shear stress.

<7> The information processing device according to <6>, in which the processor (10) estimates a friction coefficient by dividing the shear stress by the pressure.

<8> The information processing device according to <7>, in which the processor (10) calculates a time evolution of a position and a velocity of an atom configuring the molecular model based on energy acquired by using the dynamics simulation, and calculates at least one of an atomic distribution, a diffusion coefficient, an orientation degree, and a viscosity of the molecular model based on the time evolution of the position and the velocity of the atom acquired by using the dynamics simulation.

<9> The information processing device according to any one of <1> to <8>, in which the processor (10) forms a database of a relationship between an interatomic distance and energy for types of two or more types of elements and combinations thereof in advance and executes the molecular dynamics simulation.

<10> The information processing device according to any one of <1> to <9>, in which the processor (10) executes a molecular dynamics simulation based on the input type of atoms or molecules forming the molecular model, the first solid wall model, and the second solid wall model and an area where the atoms or molecules exist.

<11> The information processing device according to any one of <1> to <10>, in which the processor (10) receives information of only molecules configuring the first solid wall model, the second solid wall model, and the molecular model, and a thickness of the molecular model in the third direction, and executes a molecular dynamics simulation based on the received information.

<12> An information processing method comprising:

defining, by a processor, a molecular model that represents a population of molecules having a thickness in a third direction with respect to a first direction, a second direction intersecting the first direction, and the third direction intersecting the first direction and the second direction, and extending in the first direction and the second direction; and a first solid wall model and a second solid wall model that represent solid walls,

executing, by the processor, molecular dynamics simulation in which a force is applied to the second solid wall model in a first model in which the first solid wall model is fixed and the molecular model is interposed between the first solid wall model and the second solid wall model, by using the force field model trained by machine learning, and

calculating, by the processor, a stress of the molecular model acquired as a result of the molecular dynamics simulation.

<13> A program configured to cause a processor (10) to execute an operation comprising:

defining a molecular model that represents a population of molecules having a thickness in a third direction with respect to a first direction, a second direction intersecting the first direction, and the third direction intersecting the first direction and the second direction, and extending in the first direction and the second direction; and a first solid wall model and a second solid wall model that represent solid walls,

executing molecular dynamics simulation in which a force is applied to the second solid wall model in a first model in which the first solid wall model is fixed and the molecular model is interposed between the first solid wall model and the second solid wall model, by using the force field model trained by machine learning, and

calculating a stress of the molecular model acquired as a result of the molecular dynamics simulation.

<14> A non-transitory computer readable medium that stores a program configured to cause a processor (10) to execute an operation comprising:

defining a molecular model that represents a population of molecules having a thickness in a third direction with respect to a first direction, a second direction intersecting the first direction, and the third direction intersecting the first direction and the second direction, and extending in the first direction and the second direction; and a first solid wall model and a second solid wall model that represent solid walls,

executing molecular dynamics simulation in which a force is applied to the second solid wall model in a first model in which the first solid wall model is fixed and the molecular model is interposed between the first solid wall model and the second solid wall model, by using the force field model trained by machine learning, and

calculating a stress of the molecular model acquired as a result of the molecular dynamics simulation.

Although the embodiments of the present disclosure are specifically described above, the present disclosure is not limited to the individual embodiments described above. Various additions, modifications, substitutions, and partial deletions can be made without departing from the conceptual idea and spirit of the present invention derived from the contents defined in the claims and equivalents thereof. For example, in all the embodiments described above, when a numerical value or a mathematical expression is used for description, the numerical value or mathematical expression is shown as an example, and the embodiment is not limited thereto. Furthermore, the order of each operation in the embodiment is shown as an example, and the present disclosure is not limited thereto.

1. An information processing device comprising:
a memory storing information on a force field model trained by machine learning; and
a processor configured to:
define a molecular model that represents a molecular structure of a target having a thickness in a third direction with respect to a first direction, a second direction intersecting the first direction, and the third direction intersecting the first direction and the second direction, and extending in the first direction and the second direction; and a first solid wall model and a second solid wall model that represent solid walls;
execute molecular dynamics simulation in which a force is applied to the second solid wall model in a first model in which the first solid wall model is fixed and the molecular model is interposed between the first solid wall model and the second solid wall model, by using the force field model, and
calculate a stress of the molecular model acquired as a result of the molecular dynamics simulation.

2. The information processing device according to claim 1, wherein
the force field model is a model based on a neural network potential (NNP).

3. The information processing device according to claim 2, wherein
the molecular dynamics simulation is executed by using an interatomic potential calculated based on the NNP.

4. The information processing device according to claim 3, wherein
the molecular model is a model showing a population of molecules, a liquid, a crystal, or an amorphous solid.

5. The information processing device according to claim 3, wherein
the processor
executes a molecular dynamics simulation in a second model in which both the first solid wall model and the second solid wall model are fixed, and
executes calculation in the first model with a result acquired in the second model as an initial state.

6. The information processing device according to claim 3, wherein
the processor executes a molecular dynamics simulation by applying a pressure along the third direction and a shear force in a direction obtained by combining the first direction and the second direction to the second solid wall model in the first model to acquire a shear stress.

7. The information processing device according to claim 6, wherein
the processor estimates a friction coefficient by dividing the shear stress by the pressure.

8. The information processing device according to claim 7, wherein
the processor
calculates a time evolution of a position and a velocity of an atom configuring the molecular model based on energy acquired by using the molecular dynamics simulation, and
calculates at least one of an atomic distribution, a diffusion coefficient, an orientation degree, or a viscosity of the molecular model based on the time evolution of the position and the velocity of the atom acquired by using the molecular dynamics simulation.

9. The information processing device according to claim 1, wherein
the processor forms a database of a relationship between an interatomic distance and energy for types of two or more types of elements and combinations thereof in advance and executes the molecular dynamics simulation.

10. The information processing device according to claim 1, wherein
the processor executes a molecular dynamics simulation based on the input type of atoms or molecules forming the molecular model, the first solid wall model, and the second solid wall model and an area where the atoms or molecules exist.

11. The information processing device according to claim 1, wherein
the processor
receives information of only molecules configuring the first solid wall model, the second solid wall model, and the molecular model, and a thickness of the molecular model in the third direction, and
executes a molecular dynamics simulation based on the received information.

12. An information processing method comprising:
defining, by a processor, a molecular model that represents a population of molecules having a thickness in a third direction with respect to a first direction, a second direction intersecting the first direction, and the third direction intersecting the first direction and the second direction, and extending in the first direction and the second direction; and a first solid wall model and a second solid wall model that represent solid walls,
executing, by the processor, molecular dynamics simulation in which a force is applied to the second solid wall model in a first model in which the first solid wall model is fixed and the molecular model is interposed between the first solid wall model and the second solid wall model, by using the force field model trained by machine learning, and
calculating, by the processor, a stress of the molecular model acquired as a result of the molecular dynamics simulation.

13. A non-transitory computer readable medium that stores a program configured to cause a processor to execute an operation comprising:
defining a molecular model that represents a population of molecules having a thickness in a third direction with respect to a first direction, a second direction intersecting the first direction, and the third direction intersecting the first direction and the second direction, and extending in the first direction and the second direction; and a first solid wall model and a second solid wall model that represent solid walls,
executing molecular dynamics simulation in which a force is applied to the second solid wall model in a first model in which the first solid wall model is fixed and the molecular model is interposed between the first solid wall model and the second solid wall model, by using the force field model trained by machine learning, and
calculating a stress of the molecular model acquired as a result of the molecular dynamics simulation.
